(19) United States
(12) Patent Application Publication
(10) Pub. No.: US 2008/0273717 A1
(43) Pub. Date: Nov. 6, 2008

(54) Audio amplifier thermal management using low frequency limiting

(76) Inventors: Gerald Willis, Brownsburg, IN (US); Matthew S. Spitznagle, Indianapolis, IN (US); Jon Douglas Zenor, Greenwood, IN (US)

Correspondence Address: MCCONNELL, DEAN;Krieg DeVault LLP, One Indiana Square, Suite 2800, Indianapolis, IN, 46204--207, US

(21) Appl. No.: 11/800,012

(22) Filed: May 3, 2007

(51) Int. Cl. H03G 5/00

(52) U.S. Cl. 381/98

(57) ABSTRACT

A digital audio speaker system for a digital audio player that includes a housing and a control unit positioned in the housing. An amplifier is positioned in the housing and connected with the control unit and a speaker system. A frame assembly is positioned in the housing that includes a motorized drive assembly. A drawer assembly is movably connected with the motorized drive assembly. The motorized drive assembly is operable to move the drawer assembly between an open position and a closed position.

### BACKGROUND

The present invention relates generally to audio amplifier systems and more particularly, to an audio amplifier system that is operable to enter into a thermal management mode once reaching an upper temperature threshold value that cools the amplifier using low frequency management.

An audio amplifier is a device for increasing the power of a signal, which in the case of audio amplifiers, is an audio signal. Audio amplifiers increase the power of a signal by taking power from a power supply and controlling the output of the amplifier to match the input signal shape, but typically have a much larger amplitude. Audio amplifiers are designed to perform optimally with audio frequencies that generally fall within frequency ranges between 20 Hertz and 20,000 Hertz, which generally corresponds to the frequency range that most humans can hear. The audio amplifier is typically the final stage in the audio playback chain and its purpose is to amplify the analog audio signal generated by a preceding stage to a level that can drive loudspeakers.

During operation audio amplifiers generate heat that needs to be dissipated before reaching a level that may cause damage to the components of the amplifier. The increasing output power utilized by today's audio systems poses serious problems for dissipating the heat produced by the audio amplifier. To prevent the audio amplifier from overheating, some amplifiers use “full frequency range” amplitude limiters. These amplitude limiters limit the amplitude of every portion of the audio signal that is input to the amplifier, regardless of the frequency of the signal, so that the audio amplifier will not generate heat above a predetermined upper level. Other audio amplifiers may simply stop or kick out once the amplifier reaches a predetermined temperature valve. Despite known methods of dissipating heat in audio amplifiers, improvements to the current methods and systems for dissipating heat are needed.

### SUMMARY

One embodiment according to the present invention discloses a unique heat dissipation system for an audio amplifier of an audio system. Other embodiments include unique apparatuses, systems, devices, hardware, methods, and combinations of these for maintaining the temperature value of an audio amplifier within safe operating levels. Further embodiments, forms, objects, features, advantages, aspects, and benefits of the present invention shall become apparent from the following description and drawings.

### BRIEF DESCRIPTION OF THE DRAWINGS

FIG. 1 is a block diagram of a representative audio system in which the inventive embodiments disclosed herein may be deployed.

FIG. 2 is a flow chart of a thermal management module or software routine.

FIG. 3 is a flow chart of a high pass filter module of the thermal management module.

FIG. 4 is a flow chart of an amplitude limiter module of the thermal management.

FIG. 5 is a block diagram of an alternative embodiment of the audio system than that disclosed in FIG. 1.

FIG. 6 is a block diagram of another alternative embodiment of the audio system than that disclosed in FIGS. 1 and 5.

FIG. 7a represents a portion of a streaming analog audio signal.

FIG. 7b represents the portion of the streaming analog audio signal illustrated in FIG. 7a having a base component removed by the high pass filter.

FIG. 8a represents a bass portion of a streaming analog audio signal.

FIG. 8b represents the bass portion of the streaming analog audio signal illustrated in FIG. 8a having a reduced amplitude valve.

FIG. 9 illustrates a frequency response plot detailing the effects of base amplitude limiting.

FIG. 10 illustrates a frequency response plot detailing the effects of base bandwidth limiting.

### DETAILED DESCRIPTION OF ILLUSTRATIVE EMBODIMENTS

For the purposes of promoting an understanding of the principles of the invention, reference will now be made to the embodiment illustrated in the drawings and specific language will be used to describe the same. It will nevertheless be understood that no limitation of the scope of the invention is thereby intended, such alterations and further modifications in the illustrated device, and such further applications of the principles of the invention is illustrated therein being contemplated as would normally occur to one skilled in the art to which the invention relates.

A audio system is disclosed that includes a unique amplification system that is operable, either through computer software or analog circuitry, to effectively cool an amplifier. In one embodiment, once the amplifier reaches a predetermined operating temperature value, a computer program product executable by a control unit causes the control unit to selectively eliminate a first select range of bass frequencies from the streaming audio signal and/or reduce an amplitude value of a second select range of bass frequencies contained in the streaming audio signal. As set forth below, in another embodiment, the computer program product may, in whole or part, be replaced by analog and/or digital circuitry.

As used herein, the term bass frequencies should be construed to cover audio frequencies traditionally found or falling in the bass range. Bass frequencies are those frequencies that have tones of low frequency or range. The audio reproduction of bass frequencies contributes, and sometimes disproportionately, to the heat generated by amplifiers during audio reproduction. In one aspect of the present invention, bass frequencies are those frequencies falling in the frequency range of about 0-300 Hz, which may vary in alternative embodiments.

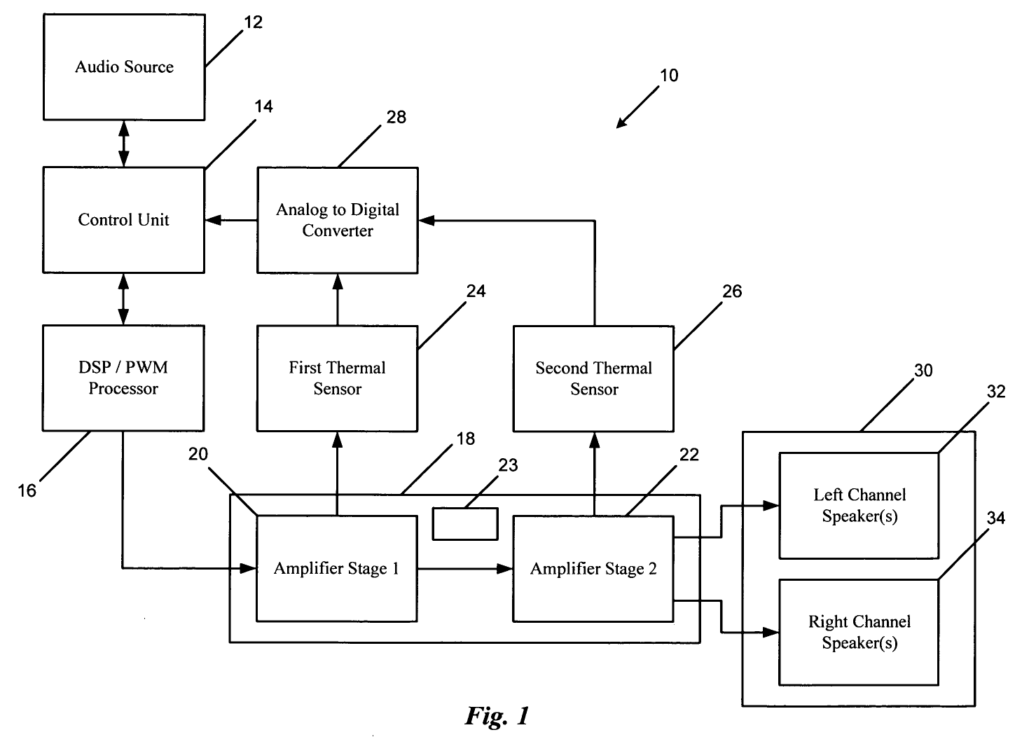

With reference to FIG. 1, an audio system 10 is illustrated that includes an audio source 12 that is capable of selectively delivering a streaming audio signal to a control unit 14. The control unit 14 may comprise one of many types of high speed microprocessor based control units that includes memory, input ports, output ports (both analog and digital), as well as on board analog-to-digital and digital-to-analog converters. The control unit 14 is connected with the audio source 12 and is capable of, in addition to receiving the streaming audio signal, controlling overall operation of the audio source 12. The audio source 12 may comprise any one or more of a number of types of audio sources known in the art such as, for example, a compact disc player, a digital video disc (“DVD”) player, a memory storage device (e.g.—hard drive, flash memory, etc.), a portable music device, and so forth.

The streaming audio signal provided by the audio source 12 is preferentially in the form of a digital audio signal, but in alternative embodiments, may comprise an analog audio signal that may then be converted to a digital audio signal by an analog-to-digital (“A/D”) converter of the control unit 14. The control unit 14 may be connected with a digital signal processor (“DSP”) or pulse width modulation processor 16 that is used to convert digital audio signals supplied by the control unit 14 to at least one analog audio signal that is supplied as an input to an amplifier 18. In alternative embodiments, more than one analog audio signal may be supplied as an input to the amplifier 18 such as, for example, two audio signals for left and right channels. The audio system 10 can use the amplifier 18, and the amplifier 18 may be designed, to amplify any number of channels, such as is the case in multi-channel audio 5.1 and 6.1 channel systems.

The amplifier 18 may comprise a single stage amplifier or a multi-stage amplifier and may be capable of amplifying the analog audio signals provided as inputs by many magnitudes. The amplifier 18 illustrated in FIG. 1 comprises a two-stage amplifier. As such, the output or analog audio signal generated by the DSP 16 is supplied as an input to a first amplifier stage 20 and the output of the first amplifier stage 20 is supplied as an input to a second amplifier stage 22. In one embodiment, the first amplifier stage 20 comprises a smoothing amplifier for smoothing out the analog audio signal provided by the DSP 16 to remove unwanted components and noise from the analog audio signal. The second amplifier stage 22 comprises a high gain amplifier operable to increase the power of the analog audio signal. One or more amplification stages may be utilized in the amplifier 18 depending on the particular use for which the audio system 10 is designed.

A first thermal sensor 24 may be connected with the first amplifier stage 20. A second thermal sensor 26 may be connected with the second amplifier stage 22. In alternative embodiments, only one thermal sensor may be used or a thermal sensor may be used for each amplification stage. The thermal sensors 24, 26 may be connected with respective heat sinks or heat dissipation members 23 of the amplifier 18 that are used to dissipate heat from the amplifier 18. However, it should be appreciated that the thermal sensors 24, 26 may be connected anywhere in the amplifier 18 where they are capable of detecting an operating temperature value of the amplifier 18.

The thermal sensors 24, 26 generate electric signals that are indicative of the operating temperature value of the amplifier 18. The readings obtained by the thermal sensors 24, 26 are transmitted to the control unit 14. In the embodiment illustrated in FIG. 1, the thermal sensors 24, 26 are connected with an A/D converter 28, which is in turn, connected to the control unit 14. The A/D converter 28 may comprise a separate circuit or may be an integral part of the control unit 14. The AND converter 28 is operable to convert analog readings obtained by the thermal sensors 24, 26 into digital temperature readings that are readily useable by the control unit 14. If the thermal sensors 24, 26 comprise digital thermal sensors, the thermal sensors 24, 26 may be connected directly to a digital input port of the control unit 14, thereby eliminating the need for the A/D converter 28.

The audio system 10 may also be connected with at least one speaker 30. In multi-channel audio systems, the audio system 10 may be connected with a plurality of speakers. The amplifier 18 is used to drive the speaker 30 to reproduce the audio recording contained in the streaming audio signal. In the embodiment illustrated in FIG. 1, the amplifier 18 includes a left channel speaker output that is connected with one or more left channel speakers 32 and a right channel speaker output that is connected with one or more right channel speakers 34. In multi-channel embodiments, the amplifier 18 may include a plurality of outputs that are targeted to different types of speakers (e.g.—woofers, sub-woofers, tweeters, and so forth).

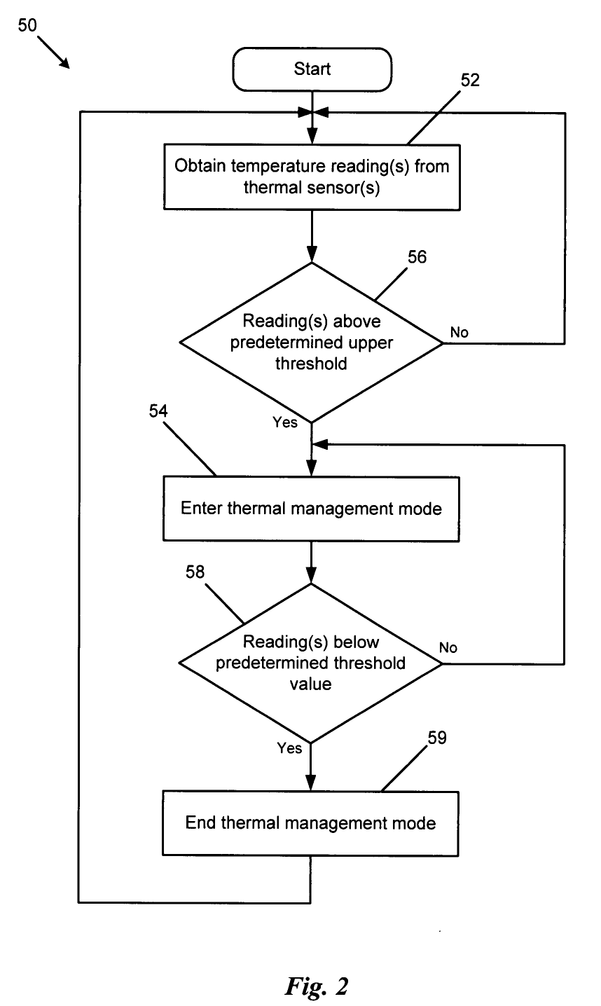

Referring to FIGS. 1 and 2, a more detailed discussion of the operation of the audio system 10 illustrated in FIG. 1, as it relates to thermal management of the amplifier 18, is set forth below. The audio system 10 includes a thermal management software routine or module 50 executable by the control unit 18 that is capable of causing the audio system 10 to enter into a thermal management mode that cools the amplifier 18 if the operating temperature value of the amplifier 18 reaches a predetermined upper threshold value. As used herein, the term module shall be construed to refer to computer programmable code that is capable of being used or executed by the control unit 14 unless indicated otherwise. The thermal management module 50 continuously monitors the operating temperature value of the amplifier 18 by monitoring the thermal sensors 24, 26, which is represented at step 52. If the operating temperature value of the amplifier 18 reaches the predetermined upper threshold valve, the thermal management module 50 enters into the thermal management mode 54, which is represented at step 56.

While the audio system 10 is operating in the thermal management mode 54, the thermal management module 50 may continue to monitor the operating temperature value of the amplifier 18 using the thermal sensors 24, 26, which is represented at step 58. If the operating temperature value of the amplifier 18 falls below a predetermined low threshold temperature value, at step 59, the thermal management module 50 ends the thermal management mode 54 of operation. The predetermined low threshold temperature value will vary from audio system to audio system depending upon several design parameters (e.g.—amplifier wattage, heat sink size, and so forth).

In one embodiment, the predetermined threshold temperature value is set somewhat below a safe operating temperature value to ensure that the amplifier 18 is adequately cooled before returning to a normal operating mode. If the operating temperature value of the amplifier 18 does not fall below the predetermined low threshold temperature value, the audio system 10 stays in the thermal management mode 54 until the temperature of the amplifier 18 reaches the predetermined low threshold temperature value. The predetermined low threshold temperature value may also vary from amplifier stage to amplifier stage, depending on the design of the amplifier 18. For example, if amplifier stages share a heat sink, one amplifier stage may not be able to operate under the same thermal conditions as the other and as such, the safe operating temperature range of that amplifier stage will take priority over the other.

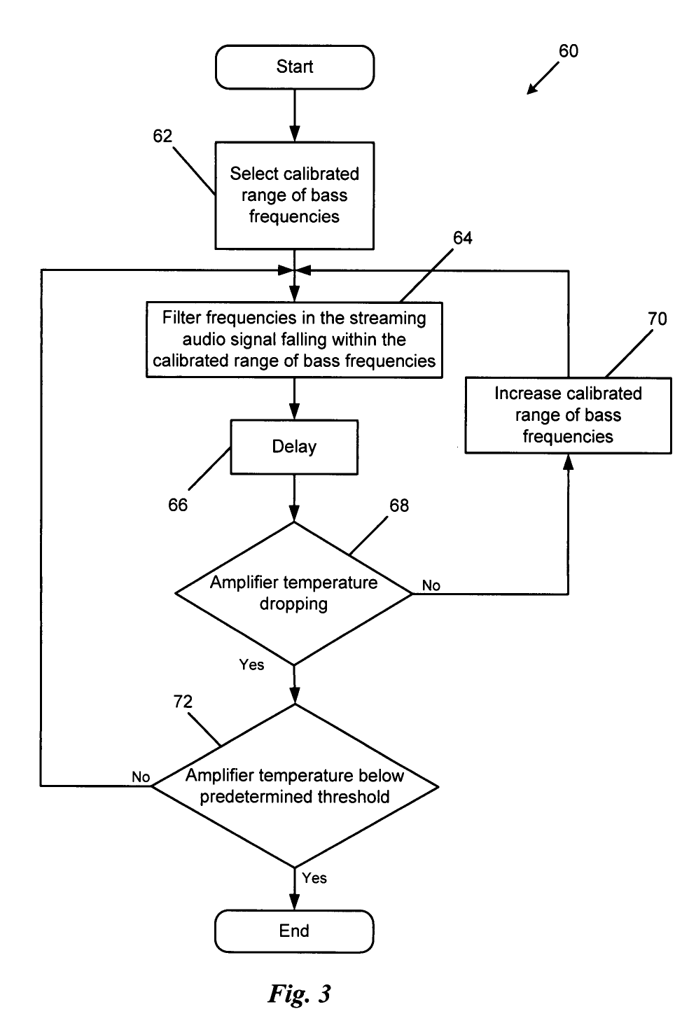

Referring to FIG. 3, when the thermal management module 50 triggers the audio system 10 to enter the thermal management mode 54, in one embodiment, a high pass filter or frequency limiter module 60 is executed by the thermal management module 50. The high pass filter module 60 is executable by the control unit 14 to remove a calibrated range of bass frequencies from audio signals contained in the streaming audio signal. The high pass filter module 60 selects or retrieves from memory a calibrated range of bass frequencies to limit to begin the process of cooling the amplifier 18, which is illustrated at step 62.

Once the calibrated range of bass frequencies has been obtained, the high pass filter module 60 begins filtering audio signals contained in the streaming audio signal falling within the calibrated range of bass frequencies, which is represented at step 64. The high pass filter module 60 may buffer the streaming audio signal in order to analyze and filter each audio signal contained in the streaming audio signal that falls within the calibrated range of bass frequencies. In one embodiment, the high pass filter module 60 completely removes or eliminates audio signals in the streaming audio signal that contain frequencies falling within the calibrated range of bass frequencies. In another embodiment, the high pass filter module 60 may only remove audio signals falling within the calibrated range of bass frequencies if the amplitude of a respective audio signal is above a predetermined threshold value. The high pass filter module 60 may use a look-ahead routine or module to analyze segments of the streaming audio signal in advance of being sent to the amplifier 18.

In one embodiment, after a predetermined amount of time has been spent filtering the streaming audio signal, which may be created by a delay timer 66, the high pass filter module 60 checks to see if the operating temperature of the amplifier 18 is decreasing, which is illustrated at step 68. If the temperature of the amplifier 18 is not decreasing, at step 70, the high pass filter module 60 may increase a bandwidth value associated with the calibrated range of bass frequencies. For example, the high pass filter module 60 may start filtering frequencies between 20-80 Hz as opposed to an initial setting of 30-60 Hz. As such, the high pass filter module 60 is operable to adjustably filter bass frequencies contained in the streaming audio signal.

If the temperature value is decreasing, at step 72, the high pass filter module 60 determines if the temperature of the amplifier 18 is below a predetermined threshold value. The temperature value at which the high pass filter module 60 ceases filtering the streaming audio signal will vary depending upon the characteristics of each particular amplifier 18. Referring back to FIG. 1, once the temperature of the amplifier 18 falls below the predetermined threshold, the thermal management module 50 may end the thermal management mode 54 of the amplifier 18 and allow it to resume normal operation, which is represented at step 59. The thermal management module 50 may have the high pass filter module 60 stop filtering by decreasing the bandwidth value of the calibrated range of bass frequencies in steps over periods of time or increments as opposed to an immediate cessation.

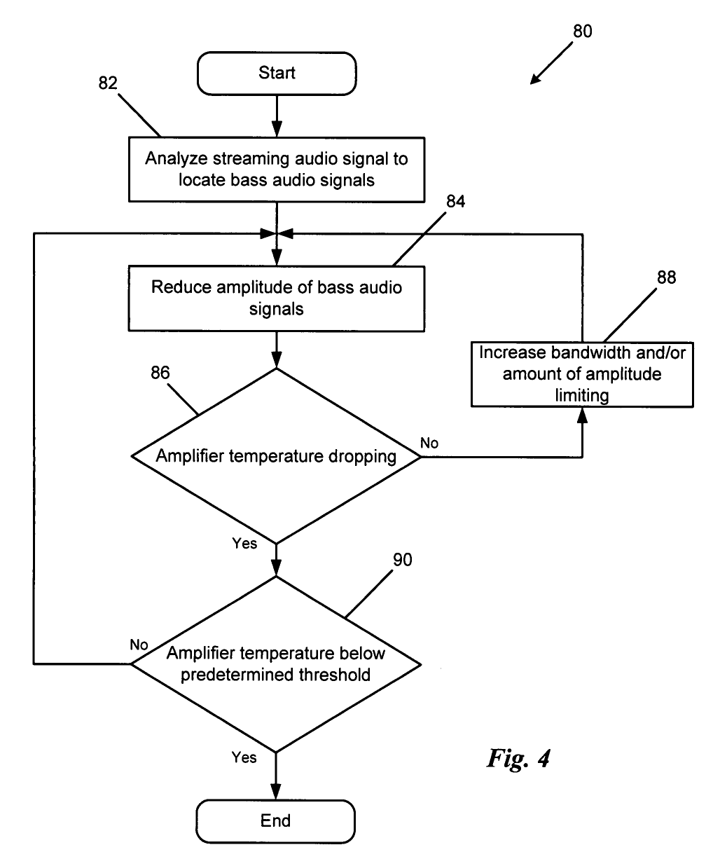

Referring to FIG. 4, in another embodiment of the audio system 10 the thermal management module 50 includes an amplitude limiter module or software routine 80 that is executable by the control unit 18 while the audio system 10 is operating in thermal management mode 54. The amplitude limiter module 80 is used to selectively lower an amplitude value associated with bass audio signals contained in the streaming audio signal that fall within a second calibrated range of bass frequencies. The thermal management module 50 may use the amplitude limiter module 80 at the same time or in conjunction with the high pass filter module 60 or by itself. At step 82, the amplitude limiter module 80 analyzes the streaming audio signal to locate bass audio signals in the streaming audio signal that fall within the second calibrated range of bass frequencies.

Once the appropriate bass audio signals are located, at step 84, the amplitude limiter module 80 adjusts the amplitude of the bass audio signals by lowering the effective amplitude of the bass audio signals. This decreases the amount of power consumed by the amplifier 18 thereby cooling the amplifier 18. The amount of amplitude adjustment that takes place may vary depending upon the design of the respective amplifier 18 and the temperature value of the amplifier 18. By way of example only, in one embodiment, the amplitude limiter module 80 may initially choose to reduce the amplitude of the bass audio frequencies by 25-35%.

The amplitude limiter module 80 also continuously monitors the temperature value of the amplifier 18, which is represented at step 86. If the temperature value of the amplifier 18 does not drop, at step 88, the amplitude limiter module 80 may increase a bandwidth value associated with the second calibrated range of bass frequencies. For example, the amplitude limiter may expand the second calibrated band of bass frequencies from 70-100 Hz to 70-120 Hz. In addition, the amplitude limiter module 80 also has the ability to increase the amount of amplitude reduction that occurs at step 84. As it relates the example set forth in the preceding paragraph, the amplitude limiter module 80 may adjust the amount of amplitude reduction from 25-35% to 35-45%, and so on. As such, the amplitude limiter module 80 is capable of reducing the amplitude of bass audio frequencies contained in the streaming audio signal and is capable of adjusting the range or bandwidth of frequencies it adjusts and the amount of amplitude adjustment that takes place.

If the temperature of the amplifier 18 is dropping, at step 90, the amplitude limiter module 80 determines if the temperature of the amplifier 18 has fallen below a predetermined threshold value, which, as previously set forth, the value of which varies depending upon the design of the amplifier 18. If the temperature of the amplifier 18 has not fallen below the predetermined threshold, the amplitude limiter module 80 continues to reduce the amplitude of bass frequencies falling within the second calibrated range of bass frequencies. Referring back to FIG. 1, if the temperature value of the amplifier 18 has fallen below the predetermined threshold, the thermal management module 50 may end the thermal management mode of the amplifier 18 and allow the audio system 10 to resume normal operation, which is represented at step 59. As with the previous embodiment, the thermal management module 50 may have the amplitude limiter module 80 slowly or incrementally cease reducing the amplitude of the frequencies as well as the bandwidth of the bass frequencies limited so that the amplifier 18 gradually resumes normal operation.

The amplitude limiter module 80 may use an amplitude control algorithm to decrease or increase a bandwidth value associated with the calibrated range of bass frequencies. If the operating temperature of the amplifier 18 continues to rise above the upper threshold value after entering thermal management mode 54, the amplitude control algorithm is operable to gradually increase the bandwidth value of the calibrated range of bass frequencies. This causes the thermal management module 60 to further limit the amplitude value of the bass frequencies thereby causing the amplifier 18 to cool faster. Once the operating temperature of the amplifier 18 falls below a predetermined threshold value, the amplitude control algorithm begins stepping down the bandwidth of the frequencies that are reduced in amplitude until normal amplification resumes.

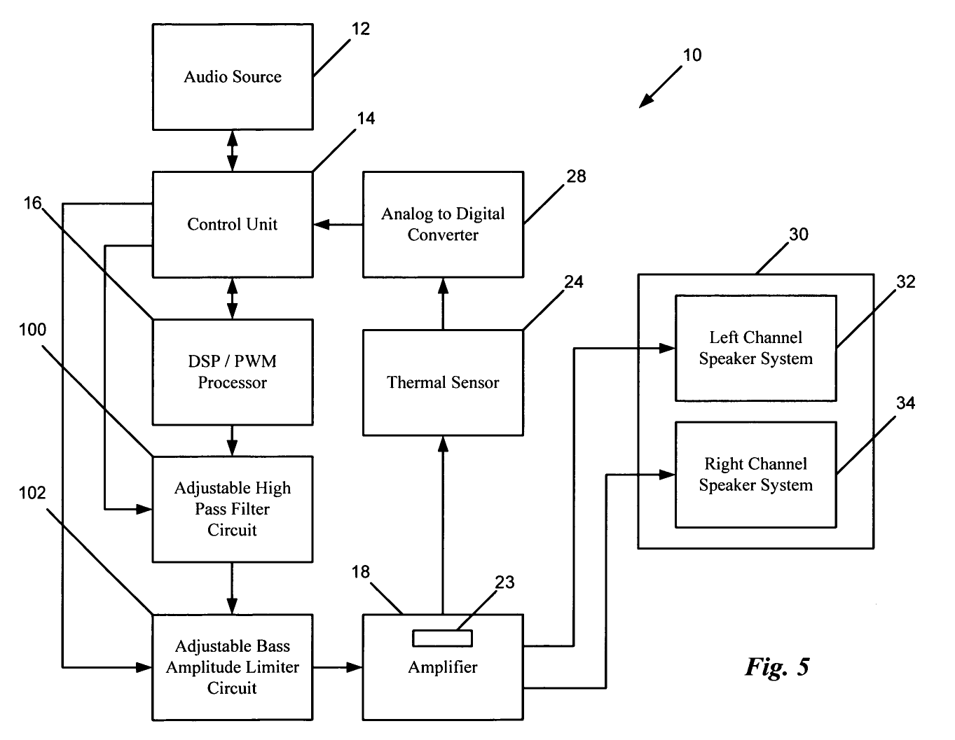

Referring to FIG. 5, in another embodiment of the audio system 10, an analog adjustable high pass filter circuit 100 is connected with an output of the control unit 14. In this embodiment, the control unit 14 transmits the streaming audio signal to the DSP 16, which converts the digital streaming audio signal into a analog streaming audio signal. The analog streaming audio signal generated by the DSP 16 is provided as an input to the analog adjustable high pass filter circuit 100. The analog streaming audio signal is then filtered by the high pass filter circuit 100, which comprises a circuit in this embodiment as opposed to software, such that it transmits frequencies above a critical bass cutoff frequency (e.g.—frequencies>80 Hz) and blocks frequencies below the cutoff value. As set forth in the previous embodiment, the control unit 18 is operable to control whether or not the adjustable high pass filter circuit 100 is functioning in addition to adjusting the bandwidth valve of the bass frequencies filtered by the adjustable high pass filter circuit 100.

As further illustrated in FIG. 5, the audio system 10 may also include an adjustable bass frequency amplitude limiter circuit 102. The adjustable bass frequency amplitude limiter circuit 102 comprises an analog/digital circuit that is designed to reduce the amplitude value of bass frequencies falling within the second calibrated range of bass frequencies. The adjustable bass frequency amplitude limiter circuit 102 is connected with an output of the DSP 16, via an output of the adjustable high pass filter circuit 100. In addition, the adjustable bass frequency amplitude limiter circuit 102 is connected with the control unit 14.

The control unit 14 is capable of selectively activating and deactivating the adjustable bass frequency amplitude limiter circuit 102. The control unit 14 is also capable of adjusting a bandwidth value of the second calibrated range of bass frequencies for which the adjustable bass frequency amplitude limiter circuit 102 will reduce the amplitudes of bass audio signals contained in the analog streaming audio signal provided by the DSP 16. In addition, the control unit 14 is also capable of adjusting the amount of amplitude reduction being provided by the adjustable bass frequency amplitude limiter circuit 102. As with the previous embodiment, this provides the audio system 10 with an adjustment that allows the adjustable bass frequency amplitude limiter circuit 102 to increase or decrease the amount of frequencies contained in the second calibrated range of bass frequencies and also allows the amount of amplitude adjustment to be selectively increased or decreased.

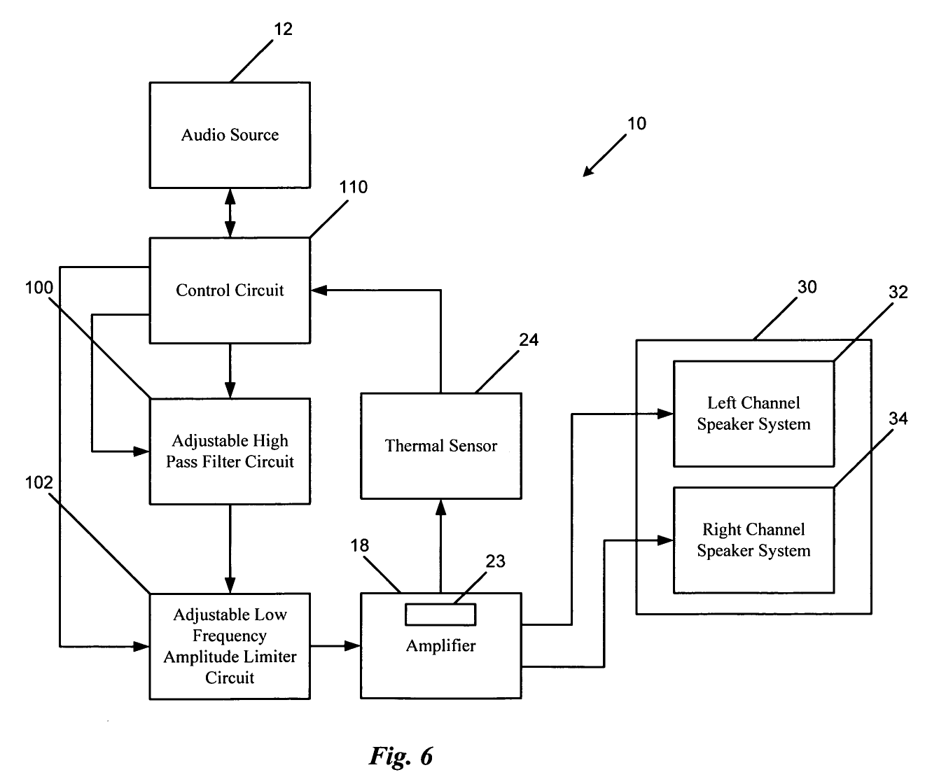

Referring to FIG. 6, yet another embodiment discloses an audio system 10 that does not take advantage of a control unit 14 or a DSP 16 as previously disclosed. This embodiment may be more relevant for smaller stand-alone systems such as portable CD or MP3 players and the like. In this embodiment, the audio source 12 is connected with a control circuit 110, which comprises a non-microprocessor based analog/digital circuit. The control circuit 110 is connected with an adjustable high pass filter circuit 100 and an adjustable bass frequency amplitude limiter circuit 102. The control circuit 110 is operable to provide the streaming analog audio signal generated by the audio source 12 to the adjustable high pass filter circuit 100 and the adjustable bass frequency amplitude limiter circuit 102. When the temperature of the amplifier 18 goes above a predetermined upper threshold, as detected by the thermal sensor 24, the control circuit 110 causes the audio system 10 to enter into thermal management mode as previously described.

In thermal management mode, the control circuit 110 is capable of selectively engaging the adjustable high pass filter circuit 100 and/or the adjustable bass frequency amplitude limiter circuit 102 to perform their respective operations, which have been set forth above in great detail in connection with the detailed description of the other embodiments disclosed herein. As such, before the streaming analog audio signal reaches the amplifier 18, the streaming analog audio signal may have had certain bass frequencies filtered or removed by the adjustable high pass filter circuit 100 and/or had certain bass frequencies lowered in amplitude by the adjustable bass frequency amplitude limiter circuit 102. This embodiment of the present invention discloses an audio system 10 that comprises an all active analog/digital circuitry solution as opposed to a microprocessor based solution.

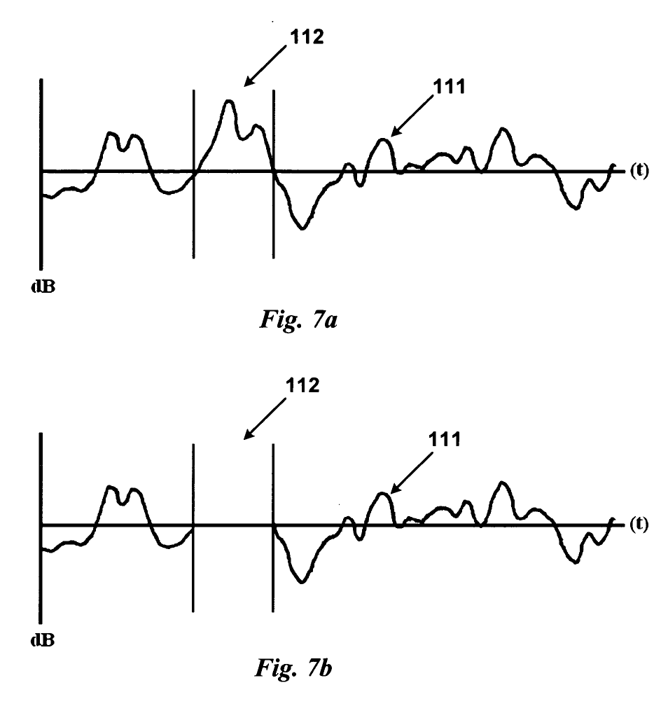

Referring collectively to FIGS. 7a and 7b, an illustration of how one example of the present invention affect an analog streaming audio signal 111 provided as an input to the amplifier 18 is illustrated. For the purpose of the following discussion, it is assumed that the audio systems 10 disclosed herein are operating in thermal management mode. The analog waveform 111 illustrated in FIG. 7a contains at least one bass frequency 112 that falls within the calibrated range of bass frequencies targeted by either the high pass filter module 60 or the high pass filter circuit 100. FIG. 7b illustrates how the bass frequency 112 of the streaming analog audio signal 111 would appear after the bass component falling within the calibrated range of bass frequencies is removed. In normal thermal management mode, all of the bass frequencies contained in the streaming audio signal illustrated in FIG. 7a falling within the calibrated range of bass frequencies would be removed or limited, thereby reducing the amount of heat generated by the amplifier 18 which in turn cools the amplifier 18.

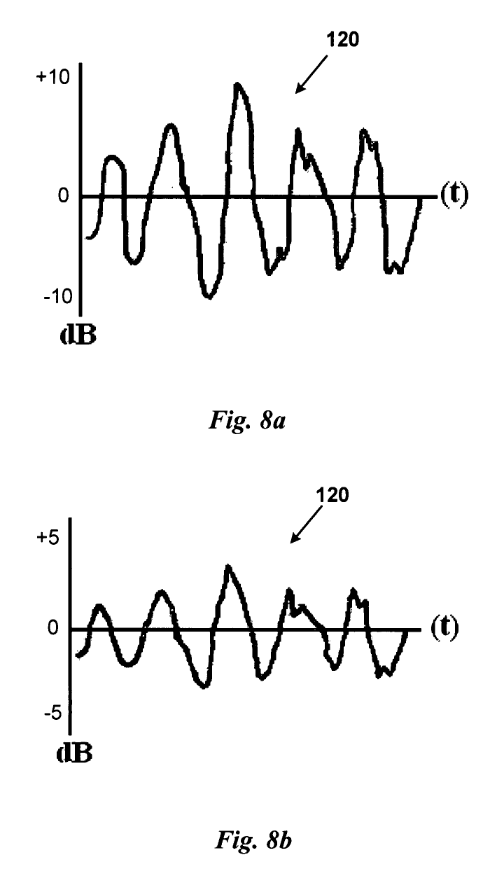

Referring collectively to FIGS. 8a and 8b, another representative illustration of how one example of the present invention affect an analog streaming audio signal 120 provided as an input to the amplifier 18 is illustrated. For the purpose of the present discussion, it should be assumed that the waveforms 120 illustrated in FIGS. 8a and 8b fall within the second calibrated range of bass frequencies. During thermal management mode, the amplitude limiter module 80 or the bass amplitude limiter circuit 102 is operable to reduce the amplitude values of frequencies contained in the streaming audio signal 120 that fall within the second calibrated range of bass frequencies. FIG. 8a illustrates how these signals would look before being reduced by either the amplitude limiter module 80 or the bass amplitude limiter circuit 102. FIG. 8b illustrates how these signals would look after being reduced by either the amplitude limiter module 80 or the bass amplitude limiter circuit 102. Reducing the amplitude of bass components of the streaming audio signal reduces the amount of heat generated by the amplifier 18.

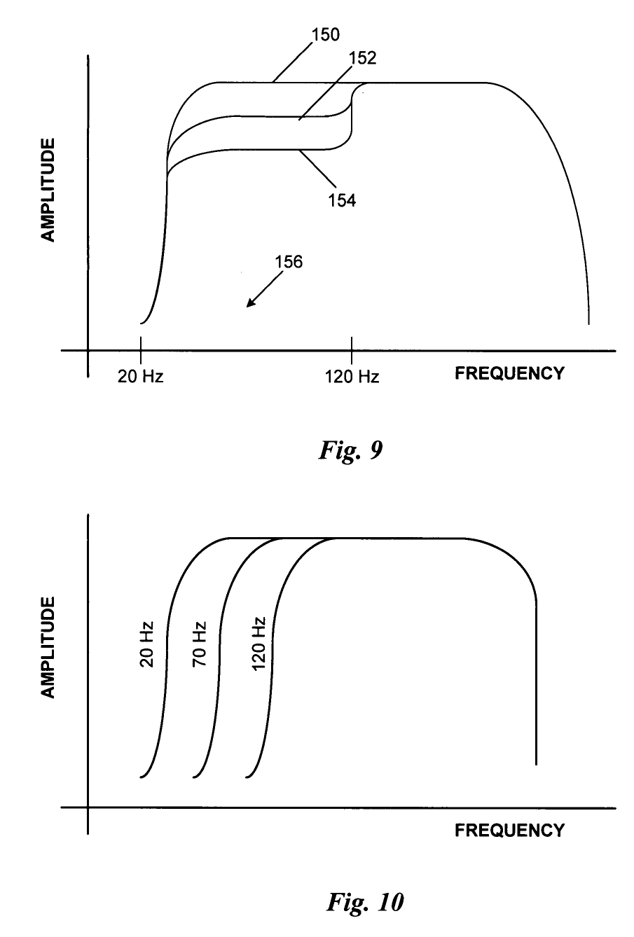

Referring to FIG. 9, a frequency response plot is illustrated detailing the effects on the audio signal created by the amplitude limiter module 80 or adjustable bass amplitude limiter circuit 102. As depicted, a first audio signal 150 having a given amplitude value is illustrated in its un-limited state. If the temperature of the amplifier 18 rises above the upper threshold limit, the amplitude limiter module 80 or circuit 102 will limit the amplitude value of the bass components of the audio signal to produce a second audio signal 152 with bass frequencies falling within a given frequency range having a limited amplitude value. If required, the amplitude limiter module 80 or circuit 102 can further limit the amplitude of the bass components to produce a third audio signal 154 having an amplitude value even lower than the second audio signal 152. As illustrated, the bass frequency range 156 affected by the amplitude limiter module 80 or circuit 102 is depicted as falling in the range of 20 Hz-120 Hz, the this range may vary in different embodiments.

Referring to FIG. 10, a frequency response plot is illustrated detailing the effects on the audio signal created by the high pass filter module 60 or adjustable high pass filter circuit 100. The high pass filter module 60 or adjustable high pass filter circuit 100 is illustrated as being capable of being set at three frequency set points. The first is 20 Hz, the second is 70 Hz, and the third is 120 Hz. If the temperature of the amplifier 18 rises above the upper threshold limit, the high pass filter module 60 or adjustable high pass filter circuit 100 filters out any frequency value falling below 20 Hz. As such, audio signals 162 having frequencies of 20 Hz or above will pass through the high pass filter module 60 or adjustable high pass filter circuit 100 while frequencies below 20 Hz are filtered out. If required, the high pass filter module 60 or circuit 100 may increase the range or bandwidth of the filtered frequencies to 70 Hz (for example) to further lower the temperature of the amplifier 18. As such, audio signals 164 having frequencies of 70 Hz or above will pass through the high pass filter module 60 or circuit 100 while frequencies below 70 Hz are filtered out. It logically follows that if the temperature of the amplifier 18 continues to rise, the high pass filter module 60 or adjustable high pass filter circuit 100 may increase the bass frequency set point to 120 Hz to further limit the amount of bass frequencies allowed to pass. As illustrated, the bass frequency range affected by the high pass filter module 60 or circuit 100 is depicted as falling in the range of 20 Hz-120 Hz, but this range and the set points utilized can vary in different embodiments.

One aspect of the present invention discloses a system comprising an audio source for selectively generating a streaming audio signal; a control unit connected with the audio source for receiving said streaming audio signal; a thermal sensor connected with an amplifier and having an output connected with the control unit, wherein the thermal sensor is operative to generate a temperature signal indicative of an operating temperature value of the amplifier; and a thermal management module executable by the control unit for controlling the amplifier in a thermal management mode that removes a calibrated range of bass frequencies from the streaming audio signal once the operating temperature value of the amplifier reaches an upper temperature threshold to thereby cool the amplifier. In yet another aspect, during the thermal management mode the thermal management module is operable to reduce an amplitude value of select audio signals in the streaming audio signal that fall within a second calibrated range of bass frequencies to a reduced amplitude value once the operating temperature value reaches the upper temperature threshold instead of, or in conjunction with, removing the calibrated range of bass frequencies.

Another aspect of the present invention discloses a method comprising means for monitoring a temperature value of at least one amplifier; means for entering a thermal management mode once the temperature value of the amplifier reaches an upper threshold, wherein the thermal management mode comprises: means for selecting a calibrated range of bass frequencies; and means for eliminating said calibrated range of bass frequencies from a streaming audio signal. In yet another embodiment, a second calibrated range of bass frequencies may be selected in conjunction with, or instead of, selecting the calibrated range of bass frequencies. In this embodiment, an amplitude value associated with select audio signals falling within the second calibrated range of bass frequencies is reduced by a predetermined amount.

Yet another aspect of the present invention discloses an amplifier comprising a control unit for receiving a streaming audio signal; a thermal sensor connected with the control unit and a heat dissipation member of the amplifier; and a high pass filter for selectively removing a calibrated range of bass frequencies from the streaming audio signal once the heat dissipation member of the amplifier reaches an upper threshold value. The amplifier may further include an amplitude limiter for limiting an amplitude value associated with select signals in the streaming audio signal that fall with a second calibrated range of bass frequencies. The amplitude limiter may be used in conjunction with the high pass filter or may be used by itself.

Another aspect of the present invention discloses a computer program product for use in an amplification system comprising computer executable program code for monitoring a temperature value of at least one amplifier; computer executable program code for entering a thermal management mode once said temperature value of said amplifier reaches an upper threshold, wherein said thermal management mode comprises: computer executable program code for selecting a first calibrated range of bass frequencies; and computer executable program code for eliminating said calibrated range of bass frequencies from a streaming audio signal. In alternative embodiments, the computer program product further comprises computer executable program code for selecting a second calibrated range of bass frequencies; and computer executable program code for computer executable program code for reducing an amplitude value of audio signals in said streaming audio signal that fall within said second calibrated range of bass frequencies.

While the invention has been illustrated and described in detail in the drawings and foregoing description, the same is to be considered as illustrative and not restrictive in character, it being understood that only the preferred embodiments have been shown and described and that all changes and modifications that come within the spirit of the inventions are desired to be protected. It should be understood that while the use of words such as preferable, preferably, preferred or more preferred utilized in the description above indicate that the feature so described may be more desirable, it nonetheless may not be necessary and embodiments lacking the same may be contemplated as within the scope of the invention, the scope being defined by the claims that follow. In reading the claims, it is intended that when words such as “a,” “an,” “at least one,” or “at least one portion” are used there is no intention to limit the claim to only one item unless specifically stated to the contrary in the claim. When the language “at least a portion” and/or “a portion” is used the item can include a portion and/or the entire item unless specifically stated to the contrary.

What is claimed is:

1. A system, comprising:
an audio source for selectively generating a streaming audio signal;
a control unit connected with said audio source for receiving said streaming audio signal;
a thermal sensor connected with an amplifier and having an output connected with said control unit, wherein said thermal sensor is operative to generate a temperature signal indicative of an operating temperature value of said amplifier; and
a thermal management module executable by said control unit for removing a calibrated range of bass frequencies from said streaming audio signal once said operating temperature value of said amplifier reaches an upper temperature threshold.

2. The system of claim 1, wherein said thermal management module is operable to variably adjust said calibrated range of bass frequencies to selectively increase or decrease a bandwidth value associated with said calibrated range of bass frequencies.

3. The system of claim 2, wherein said calibrated range of bass frequencies increases as a function of an increase in said operating temperature value of said amplifier and decreases as a function of a decrease in said operating temperature value of said amplifier.

4. The system of claim 1, wherein said thermal management module is further operable to reduce an amplitude value of select audio signals contained in said streaming audio signal that fall within a second calibrated range of bass frequencies to a reduced amplitude value once said operating temperature value reaches a second upper temperature threshold.

5. The system of claim 4, wherein said thermal management module is operable to selectively increase or decrease a bandwidth value associated with said second calibrated range of bass frequencies as a function of said operating temperature value of said amplifier.

6. The system of claim 5, wherein said thermal management module includes an amplitude control algorithm operable to gradually increase said bandwidth value associated with said second calibrated range of bass frequencies as said operating temperature value of said amplifier continues to rise above said upper temperature threshold and to gradually decrease said bandwidth value associated with said second calibrated range of bass frequencies once said operating temperature value falls below a predetermined threshold.

7. The system of claim 4, further comprising an amplitude limiter circuit connected with said control unit, wherein said streaming audio signal is directed to said amplitude limiter circuit before reaching said amplifier, wherein said amplitude limiter circuit selectively reduces said amplitude value of said select audio signals falling within said second calibrated range of bass frequencies in response to control signals received from said control unit.

8. The system of claim 1, wherein a frequency limiter module executable by said control unit removes said calibrated range of bass frequencies from said streaming audio signal.

9. The system of claim 8, wherein said frequency limiter module analyzes segments of said streaming audio signal in advance of being sent to said amplifier and removes any frequency component of an analyzed segment that fall within said calibrated range of bass frequencies.

10. The system of claim 1, further comprising a high pass filter circuit connected with and controlled by said control unit for selectively removing select portions of said streaming audio signal that fall within said calibrated range of bass frequencies.

11. The system of claim 10, wherein said high pass filter circuit comprises an adjustable high pass filter operable to selectively increase or decrease a bandwidth value associated with said calibrated range of bass frequencies.

12. A method of dissipating heat in an amplification system, comprising:
monitoring a temperature value of at least one amplifier;
entering a thermal management mode to cool said amplifier once said temperature value of said amplifier reaches an upper threshold, wherein said thermal management mode comprises:
selecting a calibrated range of bass frequencies; and
eliminating said calibrated range of bass frequencies from a streaming audio signal.

13. The method of claim 12, further comprising the step of exiting said thermal management mode once said temperature value of said amplifier falls below a predetermined threshold.

14. The method of claim 12, wherein said calibrated range of bass frequencies is eliminated from said streaming audio signal using a high pass filter module executable by a control unit.

15. The method of claim 12, wherein said calibrated range of bass frequencies is eliminated from said streaming audio signal using an analog high pass filter circuit.

16. The method of claim 12, wherein said thermal management mode further comprises selecting a second calibrated range of bass frequencies and reducing an amplitude value of any signal contained in said streaming audio signal that falls within said second calibrated range of bass frequencies.

17. The method of claim 16, wherein an amplitude limiter module executable by a control unit is used to reduce said amplitude value.

18. The method of claim 16, wherein an analog amplitude limiter circuit is used to reduce said amplitude value.

19. An amplifier, comprising:
a control unit for receiving a streaming audio signal;
a thermal sensor connected with said control unit and a heat dissipation member of said amplifier for generating an electric signal indicative of an operating temperature value of said amplifier; and
a high pass filter for selectively removing a calibrated range of bass frequencies from said streaming audio signal once said heat dissipation member reaches an upper threshold value.

20. The amplifier of claim 19, further comprising an amplitude limiter for limiting an amplitude value of select signals in said streaming audio signal that fall with a second calibrated range of bass frequencies.

21. The amplifier of claim 20, wherein said amplitude limiter comprises computer executable program code executable by said control unit.

22. The amplifier of claim 21, wherein after a predetermined amount of time has passed once said heat dissipation member of said amplifier reaches said upper threshold value said amplitude limiter is operable to increase a bandwidth value associated with said second calibrated range of bass frequencies.

23. The amplifier of claim 20, wherein said amplitude limiter comprises a circuit connected with said control unit.

24. The amplifier of 19, wherein said high pass filter comprises a computer executable program code executable by said control unit.

25. The amplifier of claim 19, wherein said high pass filter comprises a high pass filter circuit connected with said control unit.

26. A system, comprising:
an audio source for selectively generating a streaming audio signal;
a control unit connected with said audio source for receiving said streaming audio signal;
a thermal sensor connected with an amplifier and having an output connected with said control unit, wherein said thermal sensor is operative to generate a temperature signal indicative of an operating temperature value of said amplifier; and
a thermal management module operable to reduce an amplitude value of select audio signals contained in said streaming audio signal that fall within a calibrated range of bass frequencies once said operating temperature value reaches an upper threshold.

27. A method of dissipating heat in an amplification system, comprising:
monitoring a temperature value of at least one amplifier;
entering a thermal management mode once said temperature value of said amplifier reaches an upper threshold, wherein said thermal management mode comprises:
selecting a calibrated range of bass frequencies; and
reducing an amplitude value of audio signals falling within said calibrated range of bass frequencies from a streaming audio signal.

28. An amplifier, comprising:
a control unit for receiving a streaming audio signal;
a thermal sensor connected with said control unit and a heat dissipation member of said amplifier; and
an amplitude limiter for limiting an amplitude value associated with select signals contained in said streaming audio signal that fall with a second calibrated range of bass frequencies.

29. A computer program product for use in an amplification system, comprising:
computer executable program code for monitoring a temperature value of at least one amplifier;
computer executable program code for entering a thermal management mode once said temperature value of said amplifier reaches an upper threshold, wherein said thermal management mode comprises:
computer executable program code for selecting a first calibrated range of bass frequencies; and
computer executable program code for eliminating said calibrated range of bass frequencies from an audio signal.

30. The computer program product of claim 29, further comprising computer executable program code for selecting a second calibrated range of bass frequencies; and computer executable program code for computer executable program code for reducing an amplitude value of audio signals in said streaming audio signal that fall within said second calibrated range of bass frequencies.
